(19) United States
(12) Patent Application Publication
(10) Pub. No.: US 2021/0280457 A1
(43) Pub. Date: Sep. 9, 2021

(54) SELF-ALIGNED BLOCK VIA PATTERNING FOR DUAL DAMASCENE DOUBLE PATTERNED METAL LINES

(71) Applicant: INTERNATIONAL BUSINESS MACHINES CORPORATION, ARMONK, NY (US)

(72) Inventors: Timothy Mathew Philip, Albany, NY (US); Nicholas Anthony Lanzillo, Wynantskill, NY (US); Daniel James Dechene, Watervliet, NY (US); Robert Robison, Rexford, NY (US)

(21) Appl. No.: 16/811,291

(22) Filed: Mar. 6, 2020

(51) Int. Cl. H01L 21/768; H01L 23/522

(52) U.S. Cl. CPC H01L 21/76811; H01L 21/76816; H01L 23/5226; H01L 21/76813; H01L 21/76897

(57) ABSTRACT

Embodiments of the present invention disclose a method and apparatus for making a multi-layer device comprising a conductive layer, a dielectric layer formed on top of conductive layer, a via pattern formed in the dielectric layer, wherein the via pattern is comprised of a plurality of channels and columns, wherein a first portion of the via pattern downwards extends through the entire dielectric layer to directly contact the conductive layer, wherein a second portion of the via pattern extends downwards without coming into direct contact with the conductive layer.

### BACKGROUND

The present invention relates generally to the field of integrated circuits, and more particularly to formation of a vias.

At sub-30 nm interconnect pitches, via alignment becomes more challenging due to overlay error. Finite overlay shift can cause via to either move away from line end or cut off by the line end causing via CD reduction. Traditional self-aligned via (SAV) mitigates this problem at 30+ nm pitches by increasing the size of the via patterning. At sub-30 nm pitches, however, this same overlay error can result in the SAV patterning touching neighboring lines.

### BRIEF SUMMARY

Additional aspects and/or advantages will be set forth in part in the description which follows and, in part, will be apparent from the description, or may be learned by practice of the invention.

Embodiments of the present invention disclose a method and apparatus for making a multi-layer device comprising a conductive layer, a dielectric layer formed on top of conductive layer, a via pattern formed in the dielectric layer, wherein the via pattern is comprised of a plurality of channels and columns, wherein a first portion of the via pattern downwards extends through the entire dielectric layer to directly contact the conductive layer, wherein a second portion of the via pattern extends downwards without coming into direct contact with the conductive layer.

A method for forming a multi-layered device comprising forming a via pattern in a first hard mask, transferring the via pattern into a second hard mask, transferring the via pattern into a dielectric layer, removing the first hard mask and removing the second hard mask to expose the via pattern in the dielectric layer, and filling the via pattern with a conductive metal.

The second hard mask is formed directly on the top surface of the dielectric layer, wherein the first hard mask is formed directly on top of the second hard mask.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a multi-layered device where a via formation will occur, in accordance with an embodiment of the present invention.

FIG. 2 illustrates a multi-layered device where a via formation will occur, in accordance with an embodiment of the present invention.

FIG. 3 illustrates a multi-layered device where a via formation will occur that utilizes a self-aligned litho etch litho etch (SALELE) process, in accordance with an embodiment of the present invention.

FIG. 4 illustrates preforming non-mandrel cuts for the start of the formation of the via pattern, in accordance with an embodiment of the present invention.

FIG. 5 illustrates a multi-layered device where a via formation will occur, in accordance with an embodiment of the present invention.

FIG. 6 illustrates a multi-layered device where a via formation will occur, in accordance with an embodiment of the present invention.

FIG. 7 illustrates a multi-layered device where a via formation will occur, in accordance with an embodiment of the present invention.

FIG. 8 illustrates a multi-layered device where a via formation will occur, in accordance with an embodiment of the present invention.

FIG. 9 illustrates a multi-layered device where a via formation will occur, in accordance with an embodiment of the present invention.

FIG. 10 illustrates a multi-layered device where a via formation will occur, in accordance with an embodiment of the present invention.

FIG. 11 illustrates a multi-layered device where a via formation will occur, in accordance with an embodiment of the present invention.

FIG. 12 illustrates a multi-layered device where a via formation will occur, in accordance with an embodiment of the present invention.

FIG. 13 illustrates a multi-layered device where a via formation will occur, in accordance with an embodiment of the present invention.

FIG. 14 illustrates a multi-layered device where a via formation will occur, in accordance with an embodiment of the present invention.

FIG. 15 illustrates a multi-layered device where a via formation will occur, in accordance with an embodiment of the present invention.

FIG. 16 illustrates a multi-layered device where a via formation will occur, in accordance with an embodiment of the present invention.

FIG. 17 illustrates a multi-layered device where a via formation will occur, in accordance with an embodiment of the present invention.

FIG. 18 illustrates a multi-layered device where a via formation will occur, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art of affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e. two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various process used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto a wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g. aluminum, copper, etc.) and insulators (e.g. various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, wherein like reference numerals refer to like elements throughout. Embodiments of the invention are generally directed to a self-aligned block (SAB) via patterning method that is compatible with standard double patterning line patterning techniques such as self-aligned double patterning (SADP) or self-aligned litho etch litho etch (SALELE). The line double patterning, whether SADP or SALELE, is performed over two hard masks, wherein the top hard mask will be referred to as the trench memorization layer, and the bottom hard mask will be referred to as the via memorization layer.

After mandrel line and cut patterning is performed, the pattern is memorized by etching it into the trench memorization layer. Proceeding mandrel trench memorization, vias for only the mandrel lines are patterned and memorized by etching vias pattern into via memorization layer. After non-mandrel line and cut patterning is performed, the pattern is memorized by etching it into the trench memorization layer. Proceeding non-mandrel trench memorization, vias for only the non-mandrel lines are patterned and memorized by etching vias pattern into via memorization layer. After both mandrel and non-mandrel lines, cuts, and vias are patterned, the memorized via pattern is then etched into the dielectric. The memorized trench pattern is then etched into the via memorization layer, and then etched into the dielectric.

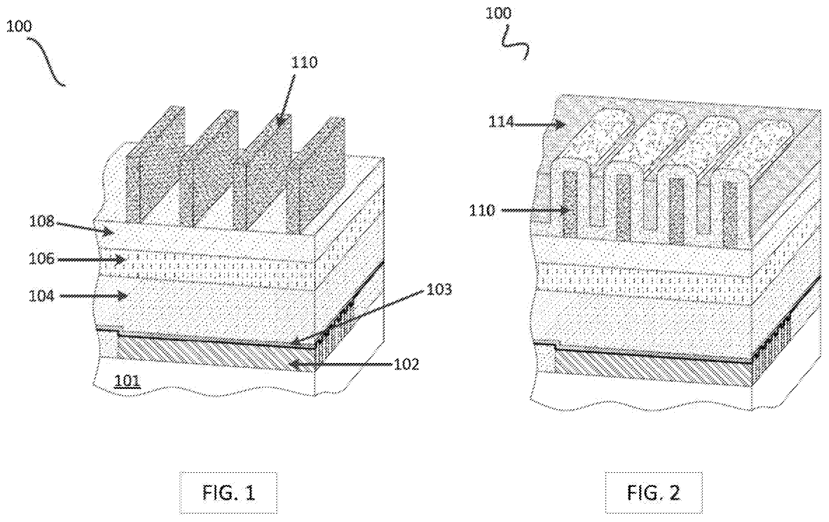

FIG. 1 illustrates a multi-layered device 100 where a via formation will occur, in accordance with an embodiment of the present invention.

The multi-layer device 100 is comprised of multiple layers, wherein the figures only illustrates a few of those layers. The multi-layer device 100 includes a substrate 101, a conductive layer 102, a nitride cap 103, a dielectric layer 104, a bottom hard mask 106, a top hard mask 108, and a mandrel 110. The substrate 101 can be, for example, a semiconductor device, a previous metal layer, or a different layer. The conductive layer 102 can be, for example, Cu, Co, Ru, a conductive metal or alloy. The dielectric layer 104 is an ultra-low k dielectric such as SiCOH. A bottom hard mask 106 is formed on the dielectric layer 104 using physical vapor deposition (PVD), chemical vapor deposition (CVD), or atomic layer deposition (ALD). The bottom hard mask 106 (the via memorization layer) can be, for example, TiN. The top hard mask 108 can be formed by utilizing PVD, CVD, or ALD. The top hard mask 108 (the trench memorization layer) can be, for example, SiN. The mandrel 110 is formed on top of the top hard mask 108 by utilizing PVD, CVD, or ALD, and the mandrel 110 material is etched by, for example, reactive ion etch (RIE), to form the mandrel 110 shape as illustrated by FIG. 1.

FIG. 2 illustrates a multi-layered device 100 where a via formation will occur, in accordance with an embodiment of the present invention.

A spacer material 112, is formed on the exposed surface of the top hard mask 108 and on the mandrels 110. The spacer material 112 can be formed by utilizing ALD to deposit the spacer material 112. The spacer material 112 can be comprised of TiOₓ. A planarization material 114 is formed on the surfaces of the spacer material 112. The amount of the planarization material 114 deposited is less than the combined height of the mandrel 110 and the spacer material 112. The planarization material 114 is deposited by utilizing a spin on coating technique. By utilizing the spin coating process, the planarization material 114 is not formed on the top surface of the spacer material 112 located on the top of the mandrels 110.

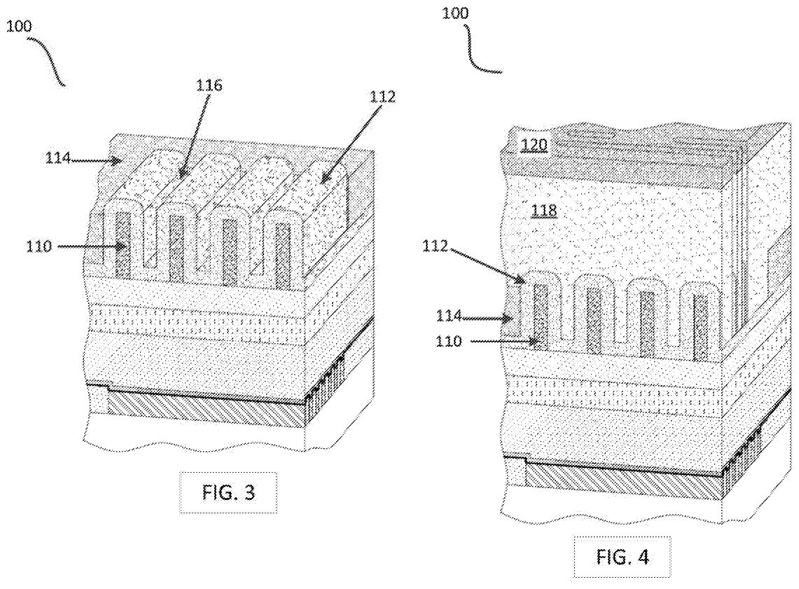

FIG. 3 illustrates a multi-layered device 100 where a via formation will occur by utilizing a self-aligned litho etch litho etch (SALELE), in accordance with an embodiment of the present invention.

A mask (not shown) is formed on the top layer of the planarization material 114 and the spacer material 112, and the mask is patterned to expose the areas located between each of the mandrels 110. This allows for the planarization material 114 located between each of mandrels 110 to be removed, through reactive ion etching (RIE). Only SALELE is explicitly illustrated by the figures. To perform a self-aligned double patterning (SADP), the fine-pitch lithography/etching done to create FIG. 3 would be replaced with a large-feature block mask pattern/etch.

FIG. 4 illustrates performing non-mandrel cuts for the start of the formation of the via pattern, in accordance with an embodiment of the present invention.

An optical planarization material (OPL) 118 is deposited to fill the gap between the spacing material 112 between the mandrels 110. A mask 120 is formed on the top layer of the planarization material 118, and the mask 120 is patterned to expose the areas to be removed through etching to make the initial non-mandrel cuts for the formation of the via pattern. The material exposed by the patterned cut mask 120 is then filled with a planarization material 114 to form non-mandrel cuts between the sidewalls of the spacer material 112. The non-mandrel cuts are the first part of the via pattern that will be formed.

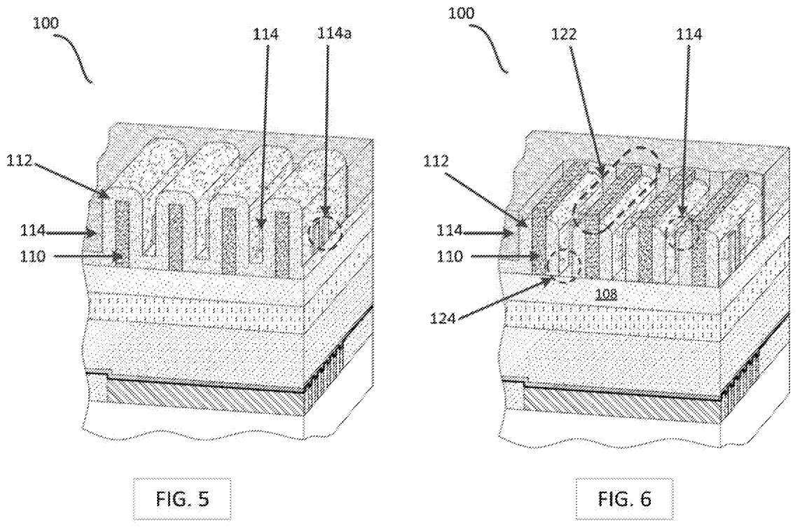

FIG. 5 illustrates a multi-layered device 100 where a via formation will occur, in accordance with an embodiment of the present invention. The non-mandrel cuts are filled in with the planarization material 114. The dashed circle 114a in FIG. 5, illustrates an example, of the planarization material 114 filling in one of the non-mandrel cuts.

FIG. 6 illustrates a multi-layered device 100 where a via formation will occur, in accordance with an embodiment of the present invention. The spacer material 112 is etched to expose the top of the mandrels 110. Dashed circle 122 illustrates one of the exposed mandrels 110. The spacer material 112 that is on the surface of the top hard mask 108 located between the mandrels 110 is removed. The spacer material 112 is removed by RIE, which allows for the target removal of the spacer material 112 to select locations. Dashed circle 124 illustrates one location where the spacer material 112 that was located between the mandrels 110 is removed to expose the top hard mask 108.

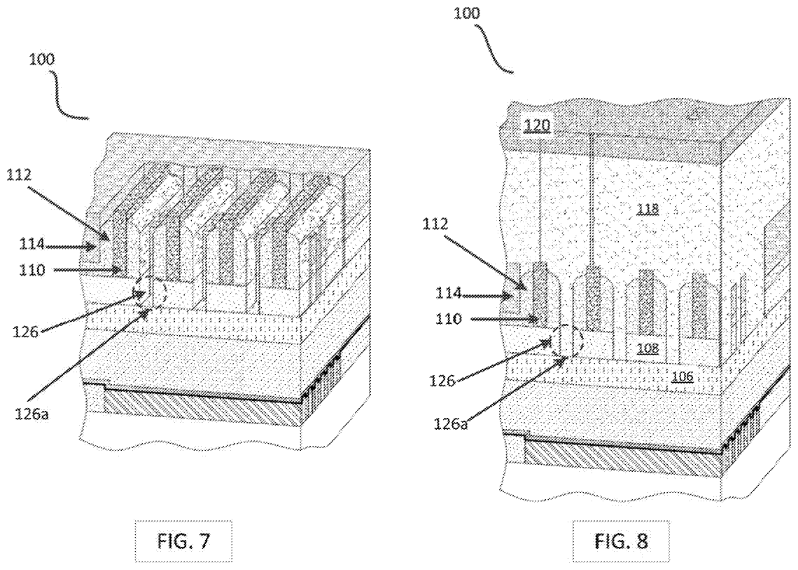

FIG. 7 illustrates a multi-layered device 100 where a via formation will occur, in accordance with an embodiment of the present invention.

The top hard mask 108 is etched, by utilizing RIE, to remove the portions of the top hard mask 108 that was exposed by the previous removal of the spacer material 112. The removal of the top hard mask 108 at the exposed locations forms a trench 126 in a desired patterned within the top hard mask 108. The dashed circle 126a in FIG. 7 illustrates one of the trenches 126 that was formed in the top hard mask 108. The etching of trench 126 etches traces of the desired pattern of the trenches 126 into the bottom hard mask 106. The desired pattern is the second part of the via pattern that will be formed.

FIG. 8 illustrates a multi-layered device 100 where a via formation will occur, in accordance with an embodiment of the present invention. An optical planarization layer 118 is formed on top of the different exposed surface layers and a mask 120 is formed on top of the OPL 118. The mask 120 is patterned in order to form a portion of the via pattern that will be etched into the bottom hard mask layer 106. The bottom hard mask 106 is etched by utilizing the via pattern created in the mask.

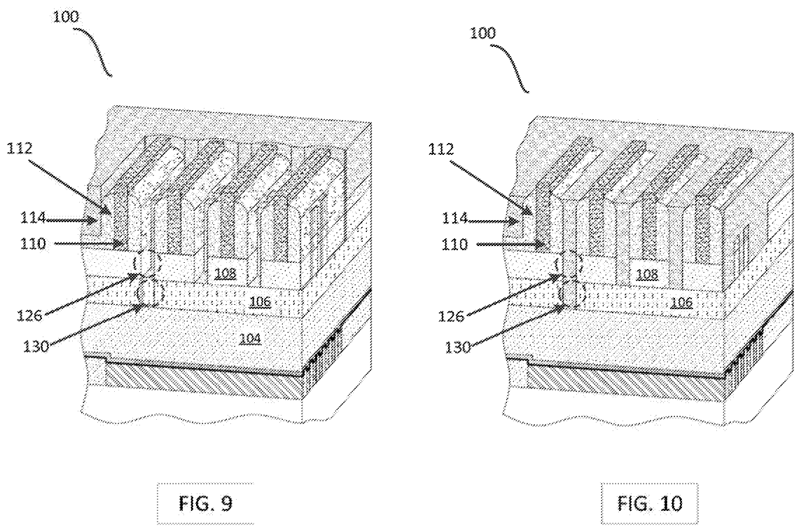

FIG. 9 illustrates the etched bottom hard mask 106 after the OPL 118 and mask 120 have been removed. The etching process causes the location of the via pattern 130 to be traced in the bottom hard mask 106. The location where a via will be formed in the pattern will be etched into the bottom hard mask 106. The dashed circle 130 highlights one of the vias in the via pattern that is formed in the bottom hard mask 106. The etching process forms a third part of the via pattern that will be formed.

FIG. 10 illustrates a multi-layered device 100 where a via formation will occur, in accordance with an embodiment of the present invention. Additional planarization material 114 is added to fill in the at least one trench 126 and the formed via in the pattern. The amount of the planarization material 114 deposited is enough to fill in the space located between mandrels 110.

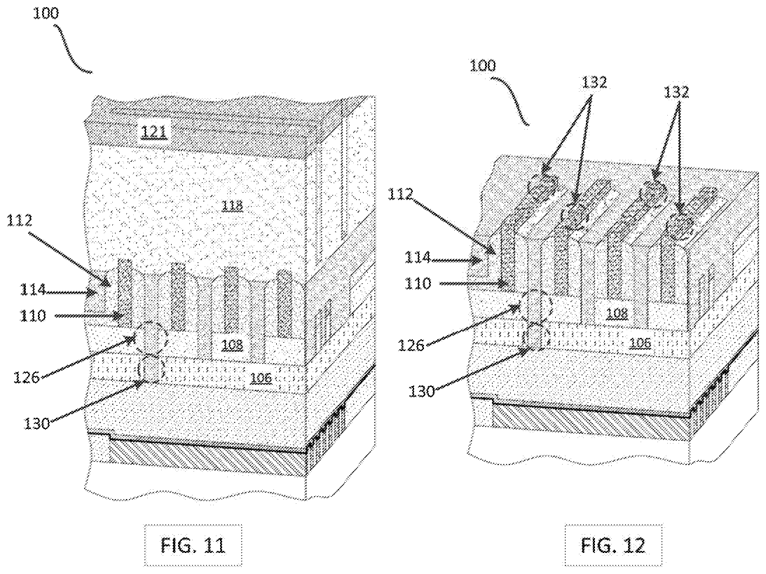

FIG. 11 illustrates a multi-layered device 100 where a via formation will occur, in accordance with an embodiment of the present invention. Another OPL layer 130 is formed on top of the mandrels 110, the planarization material 114, and the exposed surface of the spacer material 112. A cut mask 121 is formed on top of the OPL layer 130. The cut mask 120 and the OPL layer 118 are patterned. The mandrels 110 are etched in the pattern that was developed in the cut mask 121 and the OPL layers 118.

FIG. 12 illustrates a multi-layered device 100 where a via formation will occur, in accordance with an embodiment of the present invention. Dashed circles 132 illustrate examples of where the mandrel 110 was cut by the etching process. The etching process of the mandrels 110 forms a fourth part of the via pattern that will be formed. The cut sections of the mandrel 110 are fill in with the planarization material 114.

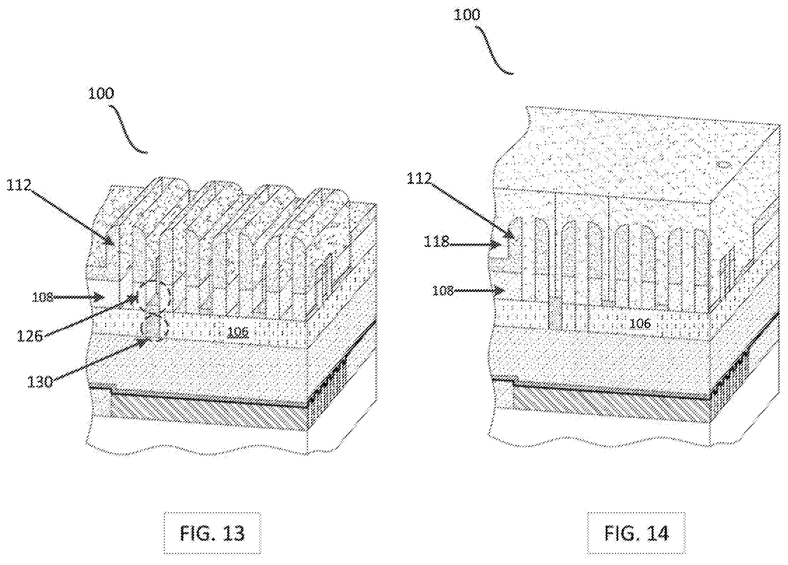

FIG. 13 illustrates a multi-layered device 100 where a via formation will occur, in accordance with an embodiment of the present invention.

The planarization material 114 is stripped, while some should remain within the etched pattern in the bottom hard mask 106. The mandrel 110 pattern and the mandrel cuts are etched into the top hard mask 108, by utilizing RIE, so that the pattern can traced into the bottom hard mask 106. The top hard mask 108 material is removed in the locations of the removed mandrels 110 and the mandrel cuts. Since the mandrel 110 cuts are etched into the top hard mask 108, the mandrel 110 cut patter can be memorized by the bottom hard mask 106. The pattern, comprised of the first, second, third, and fourth parts of the via pattern, is traced into the bottom hard mask 106 since the etching process of the top hard mask 108 passes along the pattern.

FIG. 14 illustrates a multi-layered device 100 where a via formation will occur, in accordance with an embodiment of the present invention. An OPL layer 118 is formed on top of the exposed surfaces prior to etch of the bottom hard mask 106.

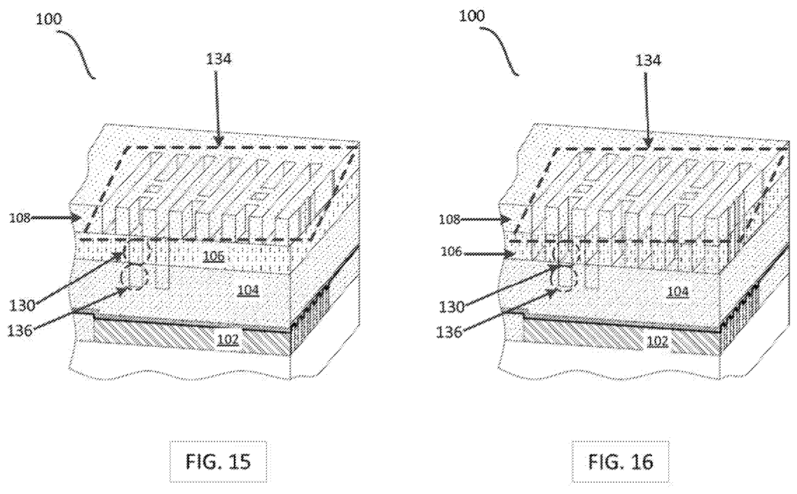

FIG. 15 illustrates a multi-layered device 100 where a via formation will occur, in accordance with an embodiment of the present invention. The planarization material 114 and the spacer material 112 is removed from the top hard mask 108. FIG. 15 illustrates the via pattern, as illustrated by enclosed section 134, that was transferred and etched into the top hard mask 108.

FIG. 16 illustrates a multi-layered device 100 where a via formation will occur, in accordance with an embodiment of the present invention. The dielectric layer 104 is etched in different locations, for example, dashed circle 136, by utilizing, for example, a RIE process. The dielectric layer 104 etched location correspond to location where the pattern was previously etched into the bottom hard mask 106, locations like dashed circle 130. The pattern is etched into the bottom hard mask 106, as illustrated by FIG. 16, thus tracing the pattern into the surface of the dielectric layer 104.

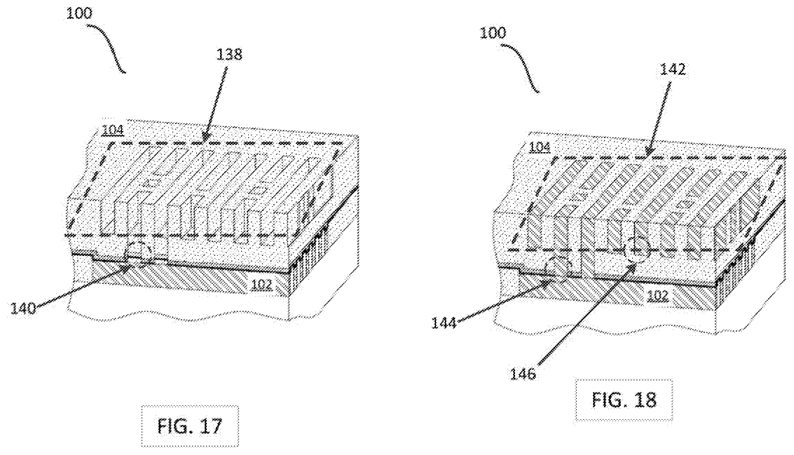

FIG. 17 illustrates a multi-layered device 100 where a via formation will occur, in accordance with an embodiment of the present invention.

The patterned is etched into the dielectric layer 104, as illustrated by dashed section 138, and the top hard mask 108 and the bottom hard mask 106 is removed. The pattern contains sections 140 that connected to the conductive layer 102.

FIG. 18 illustrates a multi-layered device 100 where a via formation will occur, in accordance with an embodiment of the present invention. The pattern is filled with a conductive metal 142, where the conductive metal 142 can be, for example, Cu, Co, Ru, a conductive metal or alloy. The conductive metal 142 can be the same metal as the conductive layer 102 or a different metal. Section 144 illustrates that the pattern contains metal filled vias that are in direct contact with the conductive layer 102.

The development of the via pattern allows for the formation of a tight via pattern formed in the dielectric layer 104. The via pattern can be developed during processing to create vias within the pattern that have different heights. FIGS. 17 and 18 illustrate that the vias within the via pattern can have different heights, for example, the via in section 140 and 144 extends downwards to directly contact the conductive metal layer 102, while the via in section 146 does extend downwards but does not directly contact the conductive metal layer 102. FIG. 18 further illustrates that not all the vias within the final pattern have the same height, see for example, section 146 illustrates that the via can extend downwards into, but not through, the dielectric layer 104. Cutting the mandrels 110, and the other non-mandrel 110 cuts, allows for the via pattern comprised of columns and channels to be precisely formed into the dielectric layer 104.

The method describes above, discloses a process for the formation of a pattern of vias that avoids overlay errors. For example, the overlay errors can be caused by the shifting of the via locations during the fabrication. The disclosed method is able to avoid these types of overlay errors.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A multi-layer device comprising:
a conductive layer;
a dielectric layer formed on top of conductive layer; and
a via pattern formed in the dielectric layer, wherein the via pattern is comprised of a plurality of channels and columns, wherein a first portion of the via pattern extends vertically downwards through the entire dielectric layer to directly contact the conductive layer, wherein a second portion of the via pattern extends vertically downwards without coming into direct contact with the conductive layer, wherein some of the plurality of channels in the via pattern can be broken up into multiple channels by sections of the dielectric layer.

2. The multi-layer device of claim 1, wherein the conductive layer is selected from the group consisting of Cu, Co, Ru, a conductive metal or alloy.

3. The multi-layered device of claim 2, wherein the via pattern is filled with a conductive metal.

4. The multi-layer device of claim 3, wherein the conductive metal used to fill the via pattern is selected from the group consisting of Cu, Co, Ru, a conductive metal or alloy.

5. The multi-layered device of claim 4, wherein the conductive metal used to fill the via pattern is comprised of a first material and the conductive layer is comprised of second material, wherein the first material and the second material are the same material.

6. The multi-layered device of claim 4, wherein the conductive metal used to fill the via pattern is comprised of a first material and the conductive layer is comprised of second material, wherein the first material and the second material are the different materials.

7. The multi-layered device of claim 1, wherein the via pattern is filled with a conductive metal.

8. The multi-layer device of claim 7, wherein the conductive metal used to fill the via pattern is selected from the group consisting of Cu, Co, Ru, a conductive metal or alloy.

9. A method comprising:
forming a via pattern in a first hard mask comprised of a first material;
transferring the via pattern into a second hard mask that is directly beneath the first hard mask, wherein the second hard mask is comprised of a second material, wherein the first material and the second material are different materials;
transferring the via pattern into a dielectric layer that is directly beneath the second hard mask;
removing the first hard mask and removing the second hard mask to expose the via pattern in the dielectric layer; and
filling the via pattern with a conductive metal:
wherein the second hard mask is formed directly on the top surface of the dielectric layer, wherein the first hard mask is formed directly on top of the second hard mask.

10. The method of claim 9, wherein the via pattern is formed sequentially in the first hard mask, then the second hard mask and final in the dielectric layer.

11. The method of claim 9, wherein forming the via pattern in the first hard mask comprises:
forming a plurality of mandrels on the top surface of the first hard mask;
forming a spacer material layer on the exposed surfaces of the first hard mask and the plurality of mandrels; and
etching the spacer material layer to form a first part of the via pattern in the first hard mask.

12. The method of claim 11, wherein forming the via pattern in the first hard mask further comprises:
filling the etched spacer material layer with a planarization material;
removing the spacer material layer located between the mandrel and located on the top surface of the first hard mask; and
etching the first hard mask to form a second part of the via pattern in the first hard mask.

13. The method of claim 12, wherein transferring the via pattern into the second hard mask comprises:
etching a portion of the second hard mask to form a third part of the via pattern.

14. The method of claim 13, wherein forming the via pattern in the first hard mask further comprises:
etching a pattern into the plurality of mandrels, wherein the etch pattern into the mandrels forms a fourth part of the via pattern in the first hard mask.

15. The method of claim 14, wherein transferring the via pattern into the dielectric layer comprises;
etching the third part of the via pattern into the dielectric layer;

16. The method of claim 15, wherein transferring the via pattern into the second hard mask further comprises:
etching the combined first part, the second part, and the fourth part of the via pattern into the second hard mask.

17. The method of claim 16, wherein transferring the via pattern into the dielectric layer further comprises:
etching the combined via pattern, composed of the first part, the second part, third part, and the fourth part of the via pattern into the dielectric layer; and
wherein the third part of the via pattern extends lower into the dielectric layer when compared to the first part, the second part, and the fourth part of the via pattern.

18. The method of claim 17, wherein the third part of the via pattern extends through the entire dielectric layer to expose an underlying conductive layer.

19. The method of claim 18, wherein filling the via pattern with a conductive metal comprises filling the first part, the second part, third part, and the fourth part of the via pattern with the conductive metal, and wherein the conductive metal filled into the third part of the via pattern is in direct contact the underlying conductive layer.

20. The method of claim 19, wherein the conductive metal used to fill the via pattern is comprised of a first material and the conductive layer is comprised of second material, wherein the first material and the second material are the same material.
